(19) United States
(12) Patent Application Publication
(10) Pub. No.: US 2018/0165495 A1
(43) Pub. Date: Jun. 14, 2018

(54) ELECTRONIC DEVICE

(71) Applicant: Fingerprint Cards AB, Goteborg (SE)

(72) Inventors: Martin GRIP, HOLLVIKEN (SE); Karl LUNDAHL, GOTEBORG (SE)

(73) Assignee: Fingerprint Cards AB, Goteborg (SE)

(21) Appl. No.: 15/814,467

(22) Filed: Nov. 16, 2017

(30) Foreign Application Priority Data
Dec. 9, 2016 (SE) 16516247

(51) Int. Cl. G06K 9/00; G06F 3/044; G06F 3/0488; G06K 9/20; H01L 23/00

(52) U.S. Cl. CPC G06K 9/0002; G06F 3/044; G06F 3/0488; G06K 9/00053; H01L 2224/48148; H01L 24/03; H01L 2224/48471; H01L 2224/04042; G06K 9/209

(57) ABSTRACT

The present invention relates to an electronic device, comprising a fingerprint sensor configured to capture an image of a fingerprint of a finger positioned on a sensor surface of the fingerprint sensor, the fingerprint sensor comprising a sensing array comprising a plurality of sensing elements, and connection pads for electrical connection to external fingerprint sensor control circuitry; and a protective plate for protecting the fingerprint sensor, the protective plate comprising conductive traces for connecting the fingerprint sensor to the external fingerprint sensor control circuitry, wherein the fingerprint sensor is attached to an underside of the protective plate and wherein the connection pads of the fingerprint sensor are mechanically and electrically connected to the conductive traces of the protective plate.

### CROSS REFERENCE TO RELATED APPLICATIONS

This application claims priority to Sweden Application No. 1651624-7 filed on Dec. 9, 2016, the disclosure of which is incorporated herein by reference in its entirety.

### FIELD

The present invention relates to an electronic device. More particularly, the present invention relates to an electronic device comprising a fingerprint sensor attached to an underside of a protective plate and to a method of manufacturing such an electronic device.

### TECHNICAL BACKGROUND

As the development of biometric devices for identity verification, and in particular of fingerprint sensing devices, has lead to devices which are made smaller, cheaper and more energy efficient, also the possible applications for such devices are increasing. In particular fingerprint sensing has been adopted more and more in, for example, consumer electronic devices, due to small form factor, relatively beneficial cost/performance factor and high user acceptance.

Capacitive fingerprint sensing devices, which may, for example, be built based on CMOS technology for providing the fingerprint sensing elements and auxiliary logic circuitry, are increasingly popular as such sensing devices can be made both small and energy efficient while being able to identify a fingerprint with high accuracy. Thereby, capacitive fingerprint sensors are advantageously used for consumer electronics, such as portable computers, tablet computers and mobile phones, e.g. smartphones.

A fingerprint sensing chip typically comprises an array of capacitive sensing elements providing a measure indicative of a capacitive coupling between several sensing structures and a finger placed on the surface of the fingerprint sensor. The sensing chip may further comprise logic circuitry for handling addressing of the array of sensing elements.

Typically, the fingerprint sensor comprises a substrate which in turn comprises readout circuitry for reading information provided by the fingerprint sensing chip. The substrate may, for example, be a conventional printed circuit board (PCB). Connecting the fingerprint sensing chip to the printed circuit board is preferably made by arranging bond wires between bond pads on the fingerprint sensing chip and bond bumps on the printed circuit board. The fingerprint sensing chip and bond wires are then covered by an over mold layer for protection.

In order to make a consumer device more aesthetically attractive, there is a desire to position the fingerprint sensor under the same front cover glass as the touch sensor and display. Hereby, improved flexibility as to where the fingerprint sensor can be positioned can be achieved, as well as improved protection against dust and moisture, etc. However, the front cover glass for the touch sensor and display is relatively thick, and using the above described conventional connecting between fingerprint sensing chip and the printed circuit board will provide a relatively large distance between the fingerprint sensing chip and the finger positioned on the front cover glass. Such large distance reduces the ability of the fingerprint sensor to acquire a correct image of the fingerprint.

According to one alternative of positioning the fingerprint sensor closer to the front cover glass is to use so-called through-silicon via (TSV) connection through the fingerprint sensing chip. Although the fingerprint sensing chip would be able to be positioned closer to the finger on the front cover glass in comparison to an over molded fingerprint sensor, using TSV requires a production method which is relatively complex and expensive.

It is thus a desire to provide an electronic device which has a reduced distance between the fingerprint sensor and the front cover glass without the need of complex and expensive production methods.

### SUMMARY

In view of the above-mentioned desired properties of an electronic device, and the above-mentioned and other drawbacks, it is an object of the present invention to provide an improved electronic device, and a method for manufacturing such a device.

According to a first aspect of the present invention, there is provided an electronic device, comprising a fingerprint sensor configured to capture an image of a fingerprint of a finger positioned on a sensor surface of the fingerprint sensor, the fingerprint sensor comprising a sensing array comprising a plurality of sensing elements, and connection pads for electrical connection to external fingerprint sensor control circuitry; and a protective plate for protecting the fingerprint sensor, the protective plate comprising conductive traces for connecting the fingerprint sensor to the external fingerprint sensor control circuitry, wherein the fingerprint sensor is attached to an underside of the protective plate and wherein the connection pads of the fingerprint sensor are mechanically and electrically connected to the conductive traces of the protective plate.

The fingerprint sensor should in the present context be understood as a sensor comprising a sensing chip comprising a plurality of sensing elements. According to a non-limiting example, the sensing element may be arranged in the form of electrically conductive plates or pads, typically arranged in an array, which are capable of forming a capacitive coupling between each sensing element and a finger placed on a sensor surface of the protective plate, i.e. an external surface relative to the fingerprint sensing surface. Through readout of a signal representative of the capacitive coupling for each sensing element, ridges and valleys of a fingerprint can be detected as a result of the distance dependence of the capacitive coupling. To achieve a fingerprint image with sufficient resolution, the sensing elements are typically substantially smaller than the features (ridges and valleys) of the finger. In general, a chip may also be referred to as a die. The fingerprint sensor control circuitry may, for example, be a portion of a control unit or the like of the electronic device, etc. arranged to e.g. receive the readout signal from the fingerprint sensor. It should however be readily understood that the present invention should not be construed as limited to the above described sensor using capacity coupling for detecting the fingerprint. Other alternatives are naturally also conceivable, such as e.g. ultrasonic fingerprint sensor or optical fingerprint sensors, etc.

The protective plate typically comprises a dielectric material in order to provide a coupling between a finger placed on the plate and the sensing elements of the sensing chip. In particular the protective plate may advantageously comprise a glass or ceramic material, such as a chemically strengthened glass, ZrO2 or sapphire. The above materials all provide advantageous properties in that they are hard and resistant to wear and tear, and in that they are dielectric thereby providing an electric coupling between a finger placed on the surface of the protective plate and the sensing element of the sensing device. The protective plate described herein commonly forms the outer surface of the fingerprint sensing device. As will also be described below, the protective plate may be the front cover glass arranged to also cover a touch sensor display and other auxiliary structures of the electronic device.

Moreover, the above described underside of the protective plate should be understood to refer to the surface of the protective plate facing the fingerprint sensor, i.e. facing away from the user of the electronic device.

The present invention is based on the insight that by providing a protective plate with conductive traces, the fingerprint sensor can be directly attached to the underside of the protective plate such that the connection pads of the fingerprint sensor is mechanically and electrically connected to the conductive traces of the protective plate for further connection to the external fingerprint sensor control circuit. The conductive traces may also be connected to other auxiliary components, such as e.g. passive or active electronic components, a host processor, etc. that may be included in a fingerprint sensor system. An advantage is hereby that the distance between the finger positioned on the upper surface of the protective plate and the sensing elements of the fingerprint sensor is reduced in comparison to an over molded fingerprint sensor, which will improve the coupling between the finger and the fingerprint sensor, while at the same time reducing the need of, for example, the complex and relatively expensive TSV solution. Also, the previous thickness penalty associated with adding a fingerprint sensor under the protective plate is reduced.

According to previous solutions, a flexible film is often mechanically connected to the fingerprint sensor for mechanically connecting the fingerprint sensing chip to the printed circuit board. A further advantage of electrically connecting the connection pads to the conductive traces of the protective plate is that there is no longer a need for mechanically connecting a flexible film to the fingerprint sensor, as such flexible film can be connected to the conductive traces of the protective plate elsewhere on the electronic device. Hereby, a reduction of mechanical stresses can be achieved in the fingerprint sensor as less material is attached to the fingerprint sensor in comparison to a situation where the flexible film is mechanically connected to the fingerprint sensor. Also, no connections and mechanical support is needed on the backside of the fingerprint sensor as the connection to the conductive traces is made on the same side of the fingerprint sensor as the sensor surface, i.e. there is no need to route electrical signals from the front side to the backside of the fingerprint sensor. A reduced risk of warpage of the fingerprint sensor is thus achieved, which warpage otherwise may yield a non-uniform bond line between the backside of the protective plate and the sensing surface of the fingerprint sensor. The ability to acquire a high quality fingerprint image is therefore improved as unwanted noise from such non-uniformity is removed. Moreover, a fingerprint sensor without a flexible film attached thereto is easier and cheaper to manufacture. Also, the absence of a flexible film reduces the thickness of the fingerprint sensor.

According to an example embodiment, the electronic device may comprise a flexible film comprising a first subset of electrically conductive traces connected to the conductive traces of the protective plate for connecting the conductive traces of the protective plate to the external fingerprint sensor control circuitry.

The flexible film may also be referred to as a flexible circuit or flexible circuit board. The flexible film thus connects the fingerprint sensor to the external fingerprint control circuitry via the first subset of electrically conductive traces. As described above, the flexible film can hereby be provided at a distance from the fingerprint sensor, thus improving the freedom of design where to position the fingerprint sensor on the electronic device. As also described above, the thickness of the fingerprint sensor can hereby be reduced.

According to an example embodiment, the protective plate may further comprise a layer arranged in contact with the fingerprint sensor, wherein the conductive traces are arranged in the layer. According to an example embodiment, the layer may be one of an ink layer, an adhesive layer or a mold layer.

It should be readily understood that the protective plate may comprise more than one layer, such as a plurality of layers. By means of a layer, or a plurality of layers, the conductive traces do not need to be attached directly to the glass or ceramic material of the protective plate.

According to an example embodiment, the electronic device may further comprise a touch sensor configured to detect the presence and location of a finger positioned on a touch surface of the touch sensor, the touch sensor comprising connection pads for connection to external touch control circuitry. Hereby, the protective plate may be a front cover glass further arranged to cover the touch sensor. Hence, the fingerprint sensor and the touch sensor are arranged under the same protective plate/front cover glass.

According to an example embodiment, the front cover glass may further comprise conductive traces on an underside of the front cover glass for connecting the touch sensor to the external touch control circuitry.

Touch sensors may use a technology where conductive traces are arranged on the backside of the front cover glass. An advantage is thus that the process for adding conductive traces for the fingerprint sensor is relatively simple as traces are already provided by means of the conductive traces used for connecting the touch sensor to the external touch control circuitry. Accordingly, when manufacturing the front cover glass with the conductive traces for the touch sensor, adding conductive traces also for the fingerprint sensor requires a minimum of modification of already existing tools and manufacturing methods for front cover glass of the touch sensors.

According to an example embodiment, the flexible film may comprise a second subset of electrically conductive traces, the second subset of electrically conductive traces of the flexible film being connected to the conductive traces of the protective plate connecting the touch sensor to the external touch control circuitry.

Hereby, the same flexible film is used for both the fingerprint sensor as for the touch sensor. An advantage is thus that a reduced number of components are required for the electronic device as only one flexible film is needed for delivery of signals to the external fingerprint sensor control circuitry and the external touch control circuitry. A further advantage is that manufacturing of the electronic device can be improved as the fingerprint sensor can be connected to an already arranged flexible film.

According to an example embodiment, the electronic device may further comprise a control unit comprising the fingerprint sensor control circuitry and the touch sensor control circuitry, wherein the first subset of electrically conductive traces is connected to the fingerprint sensor control circuitry and the second subset of electrically conductive traces is connected to the touch sensor control circuitry.

Hereby, the fingerprint sensor and the touch sensor are connected to separate control circuitry of the control unit. The control unit is thus the unit receiving the signals from the fingerprint sensor as well as from the touch sensor.

According to an example embodiment, the fingerprint sensor may be positioned on the same side of the electronic device as the touch sensor. According to an alternative example embodiment, the fingerprint sensor may be positioned on a side portion of the electronic device, which side portion is located substantially perpendicular to the surface of the touch sensor. According to a still further alternative example embodiment, the fingerprint sensor may be positioned on a backside surface of the electronic device in relation to the surface of the touch sensor. Furthermore, if more than one fingerprint sensor is used, the fingerprint sensors may be positioned on separate sides of the electronic device.

Hence, the fingerprint sensor can be arranged at various positions on the electronic device. When positioning the fingerprint sensor on the side portion or on the backside surface of the electronic device, the protective plate is preferably bent to also protect the fingerprint sensor at these positions, or the electronic device comprises a plurality of protective plates using suitable electrical connections there between. Accordingly, the protective plate is, for these embodiments, preferably also arranged on the front side surface of the electronic device, such as the above described front cover glass.

According to an example embodiment, the fingerprint sensor may be a capacitive fingerprint sensor. A capacitive fingerprint sensor is advantageous as it can be made relatively small and energy efficient while being able to identify a fingerprint with high accuracy. However, the above described embodiments can equally as well be implemented and provide advantages for ultrasonic and/or optical fingerprint sensors.

According to a second aspect of the present invention, there is provided a method of manufacturing an electronic device, comprising the steps of providing a fingerprint sensor comprising a sensing array comprising a plurality of sensing elements, and connection pads for connection to external fingerprint sensor control circuitry; providing a protective plate comprising conductive traces; attaching the fingerprint sensor to an underside of the protective plate; and connecting the connection pads of the fingerprint sensor mechanically and electrically to the conductive traces of the protective plate.

Hereby, an efficient method is provided for manufacturing of the electronic device. Also, as described above, as the protective plate may already be provided with conductive traces, it is relatively simple to also provide conductive traces for the fingerprint sensor.

According to an example embodiment, the electronic device may further comprise a flexible film comprising a first subset of electrically conductive traces, wherein the method may further comprise the steps of connecting the first subset of electrically conductive traces of the flexible film to the conductive traces by attaching the flexible film the underside of the protective plate.

According to an example embodiment, the method may further comprise the steps of providing a touch sensor comprising connection pads for connection to external touch control circuitry; attaching the touch sensor to an underside of a front cover glass, the front cover glass comprising conductive traces on an underside of the front cover glass; and connecting the connection pads of the touch sensor to the conductive traces. The front cover glass may also be provided with a layer, such as e.g. an ink layer. Hereby, the conductive traces may be provided to the layer of the front cover glass.

According to an example embodiment, the flexible film may further comprise a second subset of electrically conductive traces, the method further comprising the step of connecting the conductive traces of the front cover glass to the second subset of electrically conductive traces of the flexible film for connecting the touch sensor to the second subset of electrically conductive traces.

Further effects and features of the second aspect are largely analogous to those described above in relation to the first aspect of the present invention.

Further features of, and advantages with, the present invention will become apparent when studying the appended claims and the following description. The skilled person realize that different features of the present invention may be combined to create embodiments other than those described in the following, without departing from the scope of the present invention.

### BRIEF DESCRIPTION OF THE DRAWINGS

These and other aspects of the present invention will now be described in more detail with reference to the appended drawings showing an example embodiment of the invention, wherein:

FIG. 1 schematically illustrates an electronic device according to an example embodiment of the invention;

FIG. 2A is an exploded view of the electronic device in FIG. 1 according to an example embodiment;

FIG. 2B schematically illustrates a fingerprint sensor and its connection to the electronic device of FIG. 2A according to an example embodiment;

FIG. 3 schematically illustrates a fingerprint sensor and its connection to the electronic device according to another example embodiment;

FIG. 4 schematically illustrates a cut out view of the fingerprint sensor and its connection to a flex film of the electronic device according to an example embodiment; and

FIG. 5 schematically illustrates a method of manufacturing an electronic device according to an example embodiment.

### DETAILED DESCRIPTION

The present invention will now be described more fully hereinafter with reference to the accompanying drawings, in which exemplary embodiments of the invention are shown. The invention may, however, be embodied in many different forms and should not be construed as limited to the embodiments set forth herein; rather, these embodiments are provided for thoroughness and completeness. Like reference character refer to like elements throughout the description.

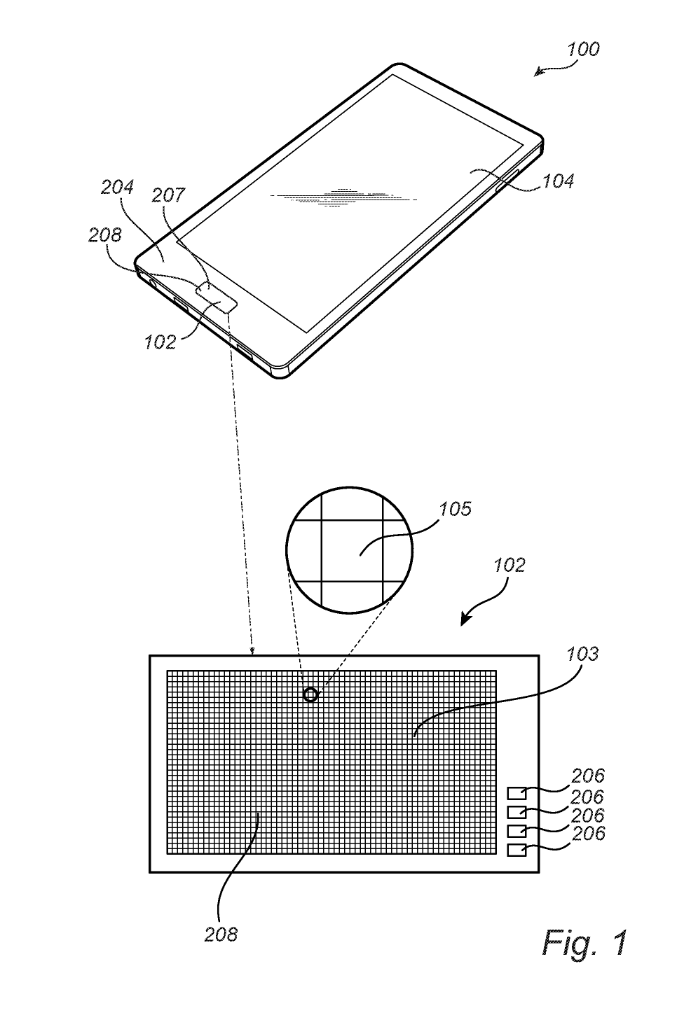

FIG. 1 is a perspective view of a schematic illustration of an electronic device 100 comprising a fingerprint sensor 102 and a touch sensor 104. The electronic device 100 is in FIG. 1 depicted as a handheld electronic device in the form of a mobile phone. However, it should be readily understood that the invention is equally applicable for other types of electronic devices such as e.g. a wearable device, a tablet, etc. Thus, the fingerprint sensor 102 can be used for such electronic devices requiring a way to identify and/or authenticate a user.

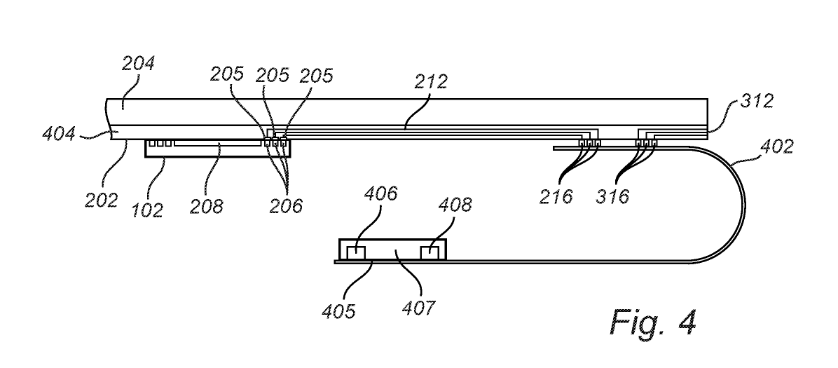

According to an example embodiment, the fingerprint sensor 102 comprises a sensor surface 208 positioned under a sensing surface 207 of a protective plate 204, which protective plate 204 is in the following also referred to as the front cover glass 204 of the electronic device 100. A finger is thus placed over the sensor surface 208, via the sensing surface 207 of the front cover glass 204. Hereby, the fingerprint sensor 102 can capture an image of the fingerprint of the user's finger. The fingerprint sensor 102 further comprises a sensing array 103 provided with a plurality of sensing elements 105. Each sensing element is configured to provide a signal indicative of an electromagnetic coupling between the sensing element and a finger placed on the sensing surface of the fingerprint sensor 102. As also depicted in FIG. 1, the fingerprint sensor 102 further comprises connection pads 206 positioned on an upper side portion of the fingerprint sensor, i.e. on the same side of the fingerprint sensor 102 as the sensor surface 208. The connection pads 206 are arranged to electrically connect the fingerprint sensor 102 to external fingerprint sensor control circuitry of e.g. a control unit (407 in FIG. 4) which may be arranged on e.g. a printed circuit board of the electronic device 100. Hence, the signals from the fingerprint sensor 102 are provided to the control unit via the connection pads 206 of the fingerprint sensor 102.

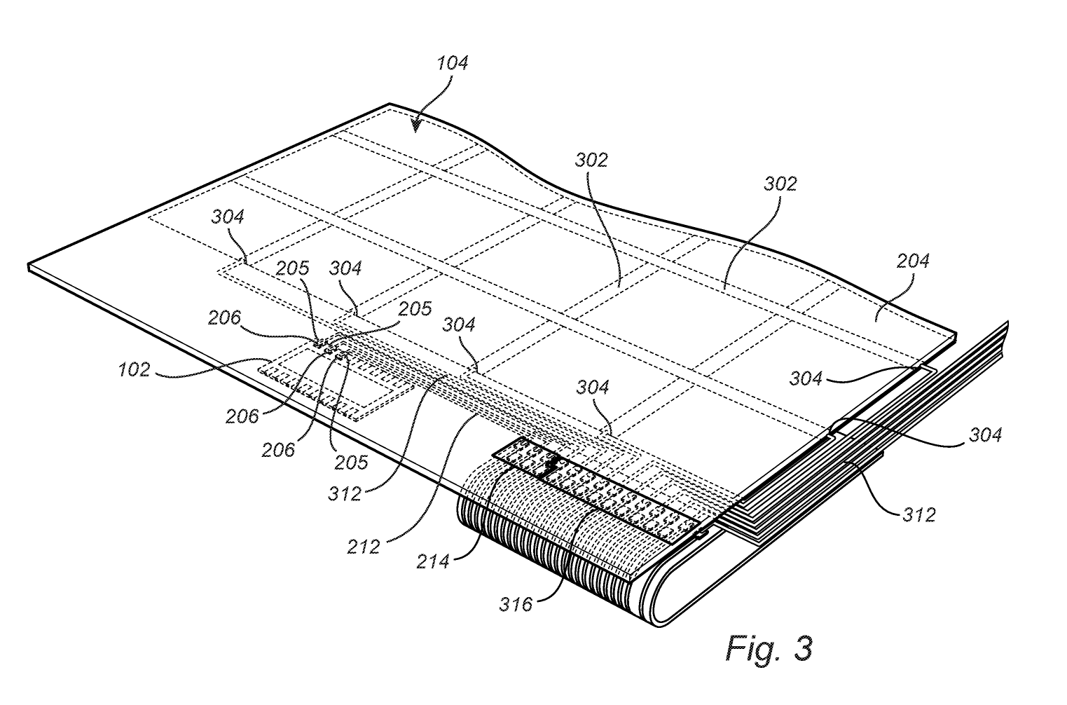

The touch sensor 104 is configured to detect the presence and location of a finger positioned on the front cover glass 204 above the touch sensor 104. Control signals from the touch sensor 104 may be provided to external touch control circuitry of e.g. the control unit of the electronic device 100. An example embodiment of how to supply the signals from the touch sensor 104 to the external touch control circuitry will be given below in relation to the description of FIG. 3.

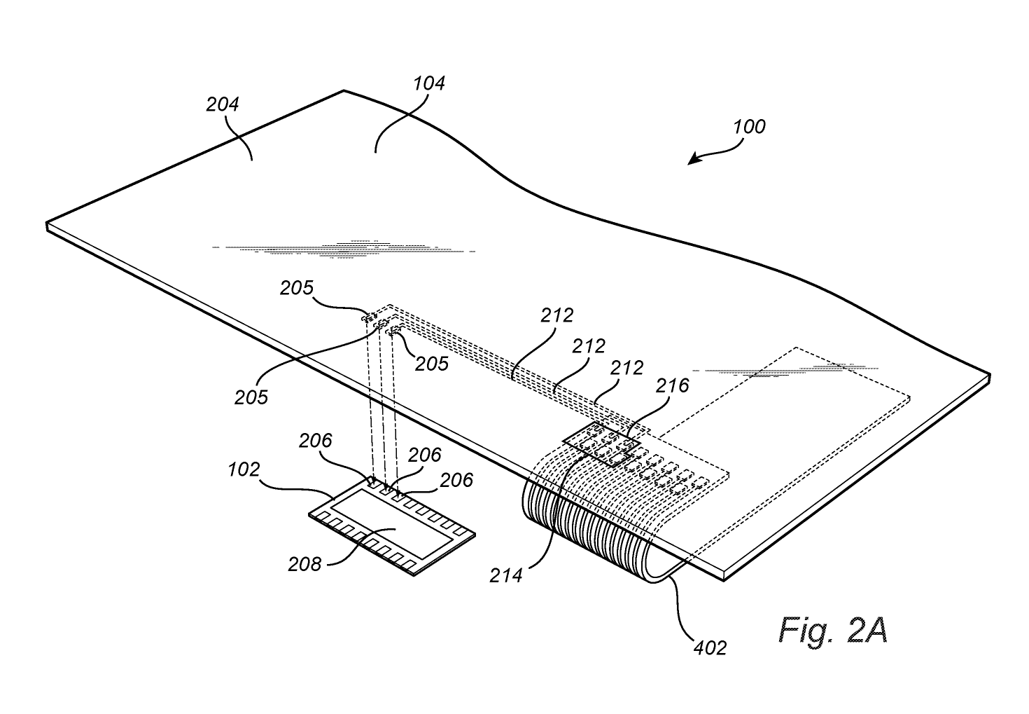

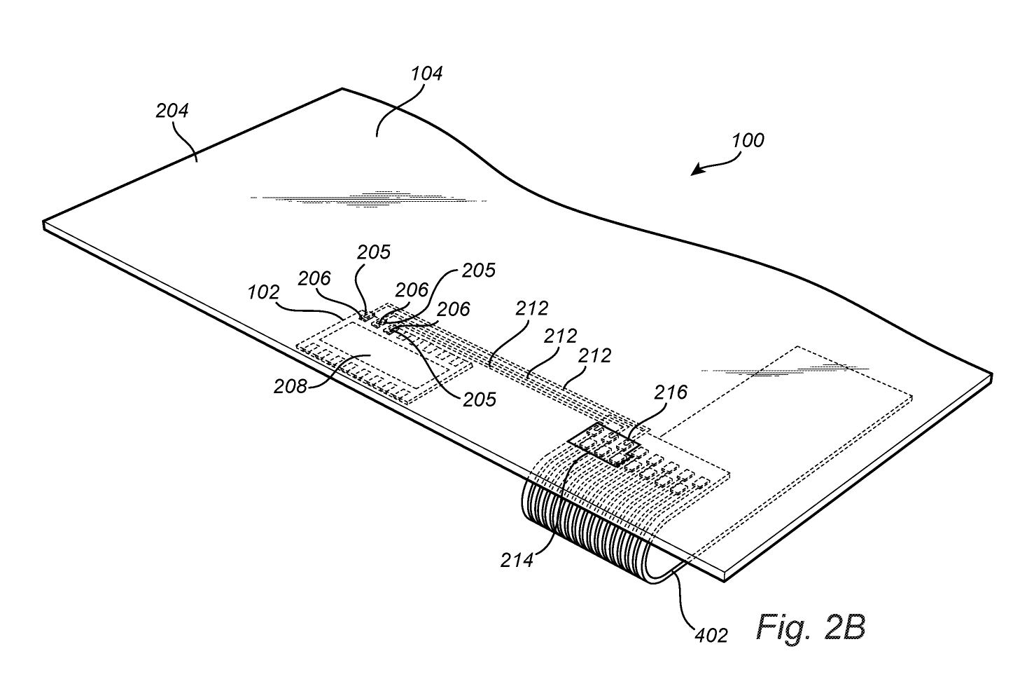

Turning now to FIGS. 2A and 2B, which schematically illustrate the fingerprint sensor 102 connected to an underside 202 of the front cover glass 204 of the electronic device 100 in an exploded view as well as in an assembled view for better understanding of the invention. The front cover glass 204 in FIGS. 2A-2B is arranged to cover the fingerprint sensor 102 as well as the touch sensor 104. Hereby, the same front cover glass 204 covers the fingerprint sensor 102 and the touch sensor 104. According to an example, the fingerprint sensor may be attached to the underside of the front cover glass by means of an adhesive. The fingerprint sensor may be attached to the underside of the front cover glass by means of a so-called anisotropic conductive film with electrical connection at the area of the connection pads 206 of the fingerprint sensor 102 and connection pads 205 of the front cover glass. Hence, no electric connection between the sensor surface 208 of the fingerprint sensor 102 and the underside of the front cover glass 204. Alternatively, so-called die attachment film can be provided on the fingerprint sensor surface for attachment to the underside of the front cover glass. The area of the connection pads 206 of the fingerprint sensor 102 and connection pads 205 of the front cover glass is in this arrangement also provided with the anisotropic conductive film for electrical connection. Other attachment alternatives are of course conceivable.

Furthermore, the electronic device 100 comprises conductive traces 212 for connecting the fingerprint sensor 102 to the external fingerprint sensor control circuitry of the electronic device 100. In particular, the conductive traces 212 are arranged on the underside 202 of the front cover glass 204 and are, as depicted in FIGS. 2A-2B, arranged with a respective connection pad 205 which is connected to the connection pads 206 of the fingerprint sensor 102. Hereby, the connection pads 206 of the fingerprint sensor 102 are electrically and mechanically connected to the conductive traces 212 of the front cover glass 204 via the connection pads 205 arranged on the underside of the front cover glass. Moreover, the conductive traces are routed and connected to a portion 214 of a flexible film 402 of the electronic device 100, which flexible film 402 is further connected to the control unit (407 in FIG. 4) of the printed circuit board (405 in FIG. 4). More particularly, the conductive traces 212 connected to the connection pads 206 of the fingerprint sensor 102 are connected to a first subset 216 of electrically conductive traces of the flexible film 402. Hereby, the signals from the fingerprint sensor 102 are provided to the external fingerprint sensor control circuitry via the connection pads 206 and the first subset 216 of electrically conductive traces of the flexible film 402.

Moreover, the front cover glass 204 may be provided with a layer (see 404 in FIG. 4) which is arranged between the front cover glass 204 and the fingerprint sensor 102. The layer 404 may, for example, be an ink layer. The layer may be arranged such that the fingerprint sensor and its components are not visually accessible by the user of the electronic device 100. Also, an additional layer of adhesive may be provided for sufficiently attaching the fingerprint sensor 102 to the front cover glass 204. Furthermore, the conductive traces 212 may be routed and arranged on the layer on the backside of the front cover glass.

Turning now to FIG. 3, which is a schematic illustration of a further example embodiment of the electronic device 100. As can be seen, the touch sensor 104 comprises a plurality of touch sensor electrodes 302 arranged to detect the presence and location of a finger positioned thereon. The touch sensor electrodes 302 may comprise so-called transceiver lines Tx and receives lines Rx. The transceiver lines Tx and the receiver lines Rx are preferably arranged perpendicular to each other and electrically isolated from each other at intersections there between. The transceiver lines Tx and the receiver lines Rx may be arranged in so-called Diamond patterns, Manhattan patterns, etc. which pattern is not limited to the scope of the present invention. Furthermore, the touch sensor electrodes 302 are attached to the underside 202 of the front cover glass 204. The touch sensor electrodes are further connected to connection pads 304 of the touch sensor 104 for connection to the external touch control circuitry.

Moreover, the connection pads 304 of the touch sensor 104 are mechanically and electrically connected to conductive traces 312 arranged on the underside of the front cover glass 204. The conductive traces 312 are further routed and connected to a second subset 316 of electrically conductive traces on the flexible film 402. Hereby, the conductive traces 312 are connected to the connection pads 304 of the touch sensor 104 and to the second subset 316 of electrically conductive traces on the flexible film in a similar manner as described above for the fingerprint sensor 102. Hereby, the touch sensor 104 and the fingerprint sensor 102 can be connected to the same flexible film 402.

In order to distinguish the conductive traces 212 connected to the connection pads 206 of the fingerprint sensor 102 from the conductive traces 312 connected to the connection pads 304 of the touch sensor 104, these conductive traces may be referred to as fingerprint conductive traces 212 and touch conductive traces 312, respectively.

Turning now to FIG. 4 which is a schematic illustration of a cut out view of the fingerprint sensor and its connection to the flex film of the electronic device according to an example embodiment. In particular, FIG. 4 is a detailed illustration of the fingerprint sensor 102 and the flexible film 402. As described above, the fingerprint sensor 102 is connected to the first subset 216 of electrically conductive traces of the flexible film 402 via the connector elements 206 of the fingerprint sensor and the fingerprint conductive traces 212 arranged on the front cover glass 204. More particularly, the fingerprint sensor 102 is attached to the underside 202 of the front cover glass 204 such that the connection pads 206 of the fingerprint sensor 102 are mechanically and electrically connected to the fingerprint conductive traces 212. Likewise, the touch sensor 104 may be connected to the second subset 316 of electrically conductive traces of the flexible film 402 by means of the touch conductive traces 312 of the front cover glass 204. As further depicted in FIG. 4, the layer 404 is arranged between the front cover glass 204 and the fingerprint sensor 102 as well as the flexible film 402. The layer 404 is also arranged between the front cover glass and the touch sensor and the touch sensor electrodes 302. Hereby, the fingerprint conductive traces 212 and the touch conductive traces 312 are routed and attached to the layer 404, which may, for example, be an ink layer.

As depicted in FIG. 4, the flexible film 402 is connected to the above described control unit 407 arranged on printed circuit board 405 of the electronic device 100. Hereby, the first subset 216 of electrically conductive traces is connected to the external fingerprint sensor control circuitry 406 of the control unit 407, while the second subset 316 of electrically conductive traces is connected to the external touch sensor control circuitry 408 of the control unit 407. The signals from the fingerprint sensor 102 and the signals from the touch sensor 104 can thereby be separated and controlled by separate systems. The control unit 407 may also be arranged without the external fingerprint sensor control circuitry 406, which in such situation can be positioned elsewhere, or the external fingerprint sensor control circuitry 406 and the external touch sensor control circuitry 408 can be arranged separated from each other.

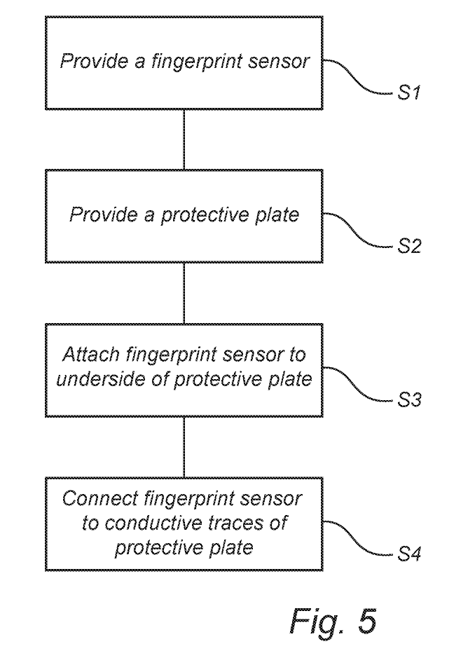

The above described electronic device is also advantageous due to its simplified manufacturing method. Reference is therefore made to FIG. 5 which schematically illustrates a method of manufacturing an electronic device according to an example embodiment.

Firstly, a fingerprint sensor 102 according to the above description is provided S1. Also, a protective plate, such as the above described front cover glass 204 comprising conductive traces 212 is provided S2. Hereby, the conductive traces 212 are bonded to the front cover glass. The conductive traces could thus be bonded to the front cover glass or to an outermost layer arranged on the front cover glass. Thereafter, the fingerprint sensor 102 is attached S3 to the underside of the protective plate 204. The attachment of the fingerprint sensor 102 to the underside of the protective plate is preferably performed by mechanically and electrically connecting S4 the connection pads 206 of the fingerprint sensor 102 to the conductive traces 212, i.e. the bond pads 205 of the protective plate 204. The step of attaching S3 the fingerprint sensor to the underside of the protective plate and the step of mechanically and electrically connecting S4 the connection pads 206 of the fingerprint sensor 102 to the conductive traces 212 is preferably executed simultaneously, i.e. at the same time. The first subset 216 of electrically conductive traces of the flexible film 402 is thereafter attached to the underside of the front cover glass such that first subset 216 of electrically conductive traces of the flexible film 402 is mechanically and electrically connected to the conductive traces 212 of the fingerprint sensor 102. Hereby, the fingerprint sensor 102 is connectable to the control unit 407 of the electronic device.

Likewise, the touch sensor 104 is attached to the underside 202 of the front cover glass 204 and the connection pads 304 of the touch sensor 104 are connected to the touch conductive traces 312 of the front cover glass for further connection to the second subset of electrically conductive traces of the flexible film.

Even though the invention has been described with reference to specific exemplifying embodiments thereof, many different alterations, modifications and the like will become apparent for those skilled in the art. Also, it should be noted that parts of the device may be omitted, interchanged or arranged in various ways, the sensor device yet being able to perform the functionality of the present invention. For example, the fingerprint sensor may be positioned on a side portion or on the backside of the electronic device. Hence, the present invention should not be construed as limited to a specific position of the fingerprint sensor.

Additionally, variations to the disclosed embodiments can be understood and effected by the skilled person in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measured cannot be used to advantage.

1. An electronic device, comprising
a fingerprint sensor configured to capture an image of a fingerprint of a finger positioned on a sensor surface of the fingerprint sensor, the fingerprint sensor comprising a sensing array comprising a plurality of sensing elements, and connection pads for electrical connection to external fingerprint sensor control circuitry; and
a protective plate for protecting the fingerprint sensor, the protective plate comprising conductive traces for connecting the fingerprint sensor to the external fingerprint sensor control circuitry, wherein the fingerprint sensor is attached to an underside of the protective plate and wherein the connection pads of the fingerprint sensor are mechanically and electrically connected to the conductive traces of the protective plate.

2. The electronic device according to claim 1, further comprising a flexible film comprising a first subset of electrically conductive traces connected to the conductive traces of the protective plate for connecting the conductive traces of the protective plate to the external fingerprint sensor control circuitry.

3. The electronic device according to claim 1, wherein the protective plate further comprising a layer arranged in contact with the fingerprint sensor, wherein the conductive traces are arranged in the layer.

4. The electronic device according to claim 3, wherein the layer is one of an ink layer, an adhesive layer or a mold layer.

5. The electronic device according to claim 1, further comprising a touch sensor configured to detect the presence and location of a finger positioned on a touch surface of the touch sensor, the touch sensor comprising connection pads for connection to external touch control circuitry.

6. The electronic device according to claim 5, wherein the protective plate is a front cover glass further arranged to cover the touch sensor.

7. The electronic device according to claim 6, wherein the front cover glass further comprises conductive traces on an underside of the front cover glass for connecting the touch sensor to the external touch control circuitry.

8. The electronic device according to claim 2, wherein the flexible film comprises a second subset of electrically conductive traces, the second subset of electrically conductive traces of the flexible film being connected to the conductive traces of the protective plate connecting the touch sensor to the external touch control circuitry.

9. The electronic device according to claim 8, further comprising a control unit comprising the fingerprint sensor control circuitry and the touch sensor control circuitry, wherein the first subset of electrically conductive traces is connected to the fingerprint sensor control circuitry and the second subset of electrically conductive traces is connected to the touch sensor control circuitry.

10. The electronic device according to claim 1, wherein the fingerprint sensor is positioned on the same side of the electronic device as the touch sensor.

11. The electronic device according to claim 1, wherein the fingerprint sensor is positioned on a side portion of the electronic device, which side portion is located substantially perpendicular to the surface of the touch sensor.

12. The electronic device according to any one of claim 1, wherein the fingerprint sensor is positioned on a backside surface of the electronic device in relation to the surface of the touch sensor.

13. The electronic device according to claim 1, wherein the fingerprint sensor is a capacitive fingerprint sensor.

14. A method of manufacturing an electronic device, comprising:
providing a fingerprint sensor comprising a sensing array comprising a plurality of sensing elements, and connection pads for connection to external fingerprint sensor control circuitry;
providing a protective plate comprising conductive traces;
attaching the fingerprint sensor to an underside of the protective plate; and
connecting the connection pads of the fingerprint sensor mechanically and electrically to the conductive traces of the protective plate.

15. The method according to claim 14, wherein the electronic device further comprises a flexible film comprising a first subset of electrically conductive traces, the method further comprising:
connecting the first subset of electrically conductive traces of the flexible film to the conductive traces by attaching the flexible film the underside of the protective plate.

16. The method according to claim 14, wherein the method further comprising:
providing a touch sensor comprising connection pads for connection to external touch control circuitry;
attaching the touch sensor to an underside of a front cover glass, the front cover glass comprising conductive traces on an underside of the front cover glass; and
connecting the connection pads of the touch sensor to the conductive traces.

17. The method according to claim 15, wherein the flexible film further comprises a second subset of electrically conductive traces, the method further comprising:
connecting the conductive traces of the front cover glass to the second subset of electrically conductive traces of the flexible film for connecting the touch sensor to the second subset of electrically conductive traces.
